(19) United States
(12) Patent Application Publication
(10) Pub. No.: US 2026/0171639 A1
(43) Pub. Date: Jun. 18, 2026

(54) SINGLE POLE DOUBLE THROW SWITCH AND METHOD OF OPERATING THE SAME

(71) Applicant: ELECTRONICS AND TELECOMMUNICATIONS RESEARCH INSTITUTE, Daejeon (KR)

(72) Inventors: Hui Dong LEE, Daejeon (KR); Sunwoo KONG, Daejeon (KR); Bong Hyuk PARK, Daejeon (KR); Seung Hun WANG, Daejeon (KR)

(73) Assignee: ELECTRONICS AND TELECOMMUNICATIONS RESEARCH INSTITUTE, Daejeon (KR)

(21) Appl. No.: 19/383,083

(22) Filed: Nov. 7, 2025

(30) Foreign Application Priority Data
Dec. 12, 2024 (KR) 10-2024-0184856
Aug. 19, 2025 (KR) 10-2025-0115302

(51) Int. Cl. H01P 1/15; H03K 17/16; H03K 17/56; H04B 1/44

(52) U.S. Cl. CPC H01P 1/15; H03K 17/16; H03K 17/56; H04B 1/44

(57) ABSTRACT

An SPDT switch operates in a transmission mode and a reception mode. The SPDT switch includes a transmission terminal, a reception terminal, an antenna terminal, and an impedance control circuit. The antenna terminal is connected to the transmission terminal and the reception terminal to transmit the transmission signal received from the transmission terminal via a first transmission line to outside based on a transmission mode, and receive the reception signal from outside and deliver the reception signal to the reception terminal via a second transmission line based on a reception mode. The impedance control circuit includes a switching element operating in ON/OFF states depending on the transmission and reception modes, and adjusts a composite capacitance between the antenna terminal and ground according to ON/OFF operations of the switching element. Thus, insertion loss can be reduced, and signal quality and noise figure can be improved.

### CROSS-REFERENCE TO RELATED APPLICATIONS

This application claims priority to Korean Patent Applications No. 10-2024-0184856, filed on December 12, 2024, and No. 10-2025-0115302, filed on August 19, 2025, with the Korean Intellectual Property Office (KIPO), the entire contents of which are hereby incorporated by reference.

### BACKGROUND

### 1. Technical Field

The present disclosure relates to a single pole double throw (SPDT) switch and a method of operating the same. More particularly, the present disclosure relates to an SPDT switch used in transmission and reception paths of a wireless communication system and a method of operating the same.

### 2. Related Art

Conventionally, a parallel type single pole double throw (SPDT) switch circuit has been widely used as an RF switch for selectively connecting a single antenna to a transmitter and a receiver.

Such a parallel SPDT switch is configured to switch a signal path between transmission and reception by connecting two single pole single throw (SPST) switches in parallel, and by configuring switching elements connected to a plurality of output terminals based on one common terminal in parallel. Accordingly, a transmission and reception path can be switched by selectively opening or shorting a desired path depending on the application of a control voltage.

A circuit including such a parallel SPDT switch has advantages in that the configuration is simple, the implementation cost is low, and the power consumption is small. Therefore, it is effectively utilized in wireless systems emphasizing low power consumption or low cost.

However, the conventional parallel SPDT switch circuit has a problem in that insertion loss increases and isolation between transmission and reception paths decreases as the frequency band increases. Therefore, in application examples where high-frequency characteristics are important, a separate optimization design or a compensation circuit is required to minimize such losses and interference.

### SUMMARY

The present disclosure for resolving the above-described problems is directed to providing a single pole double throw (SPDT) switch capable of reducing insertion loss and improving signal quality and noise figure.

The present disclosure is also directed to providing a wireless communication system including an SPDT switch capable of reducing insertion loss and improving signal quality and noise figure.

The present disclosure is also directed to providing a method of operating an SPDT switch capable of reducing insertion loss and improving signal quality and noise figure.

According to an exemplary embodiment of the present disclosure, a single pole double throw (SPDT) switch operates in a transmission mode and a reception mode. The SPDT switch includes a transmission terminal, a reception terminal, an antenna terminal, and an impedance control circuit. A transmission signal is applied to the transmission terminal. A reception signal is delivered to the reception terminal. The antenna terminal is connected to the transmission terminal and the reception terminal. The antenna terminal transmits the transmission signal received from the transmission terminal via a first transmission line to outside based on a transmission mode, and receives the reception signal from outside and deliver the reception signal to the reception terminal via a second transmission line based on a reception mode. The impedance control circuit is connected between the antenna terminal and ground. The impedance control circuit includes at least two capacitors and a switching element operating in ON/OFF states depending on the transmission mode and the reception mode. The impedance control circuit adjusts a composite capacitance between the antenna terminal and ground according to ON/OFF operations of the switching element.

In an exemplary embodiment, the impedance control circuit may provide a first composite capacitance in the transmission mode, and provide a second composite capacitance smaller than the first composite capacitance in the reception mode.

In an exemplary embodiment, the impedance control circuit may form the first composite capacitance by connecting a plurality of capacitors in parallel in the transmission mode, or form the second composite capacitance by connecting a plurality of capacitors in series in the reception mode.

In an exemplary embodiment, the impedance control circuit may include a first capacitor connected between the antenna terminal and ground, and a second capacitor connected between the first capacitor and ground. The switching element may be connected between the first capacitor and ground and connected in parallel with the second capacitor.

In an exemplary embodiment, the switching element may operate in an ON state in the transmission mode such that among the first capacitor and the second capacitor, the second capacitor is deactivated and only the first capacitor operates, and operate in an OFF state in the reception mode such that the first capacitor and the second capacitor operate in series.

In an exemplary embodiment, the impedance control circuit may include a first capacitor connected between the antenna terminal and ground, and a second capacitor connected between the antenna terminal and ground in parallel with the first capacitor. The switching element may be connected in series between the second capacitor and ground.

In an exemplary embodiment, the switching element may operate in an ON state in the transmission mode such that the first capacitor and the second capacitor operate in parallel, and operate in an OFF state in the reception mode such that among the first capacitor and the second capacitor, the second capacitor is deactivated and only the first capacitor operates.

In an exemplary embodiment, the SPDT switch may further include a transmission-side switching element connected in parallel with the first transmission line formed between the transmission terminal and the antenna terminal.

In an exemplary embodiment, the transmission-side switching element may include a plurality of switching elements connected in series such that one side is connected to the transmission terminal and the other side is connected to ground.

In an exemplary embodiment, the SPDT switch may further include a reception-side switching element connected in parallel with the second transmission line formed between the reception terminal and the antenna terminal.

In an exemplary embodiment, the SPDT switch may further include a transmission-side switching element connected in parallel with the first transmission line formed between the transmission terminal and the antenna terminal, and a reception-side switching element connected in parallel with the second transmission line formed between the reception terminal and the antenna terminal. Based on the transmission-side switching element being in an OFF state and the reception-side switching element being in an ON state, the first transmission line may be activated and the second transmission line may be deactivated such that the transmission mode operates. Based on the transmission-side switching element being in an ON state and the reception-side switching element being in an OFF state, the first transmission line may be deactivated and the second transmission line may be activated such that the reception mode operates.

In an exemplary embodiment, the SPDT switch may further include a first inductor connected in series with the transmission terminal on the first transmission line.

In an exemplary embodiment, the SPDT switch may further include a second inductor connected in series with the reception terminal on the second transmission line.

In an exemplary embodiment, the transmission signal and the reception signal may include a radio frequency (RF) signal.

According to an exemplary embodiment of the present disclosure, a wireless communication system includes a transmitter, a receiver, and an SPDT switch. The transmitter transmits a transmission signal. The receiver receives a reception signal. The SPDT switch is connected respectively to the transmitter and the receiver, shares a common antenna, and operates in a transmission mode and a reception mode. The SPDT switch includes a transmission terminal, a reception terminal, an antenna terminal, and an impedance control circuit. The transmission signal is applied to the transmission terminal. The reception signal is delivered to the reception terminal. The antenna terminal is connected to the transmission terminal and the reception terminal. The antenna terminal transmits the transmission signal received from the transmission terminal via a first transmission line to outside based on the transmission mode, and receives the reception signal from outside and deliver the reception signal to the reception terminal via a second transmission line based on the reception mode. The impedance control circuit is connected between the antenna terminal and ground. The impedance control circuit includes at least two capacitors and a switching element operating in ON/OFF states depending on the transmission mode and the reception mode. The impedance control circuit adjusts a composite capacitance between the antenna terminal and ground according to ON/OFF operations of the switching element.

In an exemplary embodiment, the impedance control circuit may provide a first composite capacitance in the transmission mode and provide a second composite capacitance smaller than the first composite capacitance in the reception mode.

In an exemplary embodiment, the impedance control circuit may include a first capacitor connected between the antenna terminal and ground, and a second capacitor connected between the first capacitor and ground. The switching element may be connected between the first capacitor and ground and may be connected in parallel with the second capacitor. The switching element may operate in an ON state in the transmission mode such that among the first capacitor and the second capacitor, the second capacitor is deactivated and only the first capacitor operates, and operate in an OFF state in the reception mode such that the first capacitor and the second capacitor operate in series.

In an exemplary embodiment, the impedance control circuit may include a first capacitor connected between the antenna terminal and ground, and a second capacitor connected between the antenna terminal and ground in parallel with the first capacitor, and the switching element may be connected in series between the second capacitor and ground. The switching element may operate in an ON state in the transmission mode such that the first capacitor and the second capacitor operate in parallel, and operate in an OFF state in the reception mode such that among the first capacitor and the second capacitor, the second capacitor is deactivated and only the first capacitor operates.

In an exemplary embodiment, the wireless communication system may further include a first inductor connected in series with the transmission terminal on the first transmission line, and a second inductor connected in series with the reception terminal on the second transmission line.

According to an exemplary embodiment of the present disclosure, a method of operating an SPDT switch is provided. The SPDT switch operates in a transmission mode and a reception mode, and includes a transmission terminal to which a transmission signal is applied, a reception terminal to which a reception signal is delivered, and an antenna terminal connected to the transmission terminal and the reception terminal. The method includes, in the transmission mode, controlling a switching element into an ON state to increase a composite capacitance between the antenna terminal and ground, and delivering the transmission signal from the transmission terminal to the antenna terminal via a first transmission line, and in the reception mode, controlling the switching element into an OFF state to decrease the composite capacitance between the antenna terminal and ground, and receiving the reception signal from outside via the antenna terminal and delivering the reception signal to the reception terminal via a second transmission line.

According to the exemplary embodiments of the present disclosure, since an impedance control circuit adjusts a composite capacitance between an antenna terminal and ground according to ON/OFF operations of a switching element, insertion loss can be reduced, and signal quality and noise figure can be improved.

In addition, a high-performance SPDT switch capable of signal switching in wireless communication equipment or RF application fields can be provided even in high-frequency and ultra-high-frequency bands.

### BRIEF DESCRIPTION OF DRAWINGS

FIG. 1 is a circuit diagram illustrating an SPDT switch according to an exemplary embodiment of the present disclosure.

FIG. 2 is a circuit diagram illustrating an equivalent capacitance representing a composite capacitance of an impedance control circuit of the SPDT switch in FIG. 1.

FIG. 3 is a graph illustrating a simulation result of S-parameters in a transmission mode of the SPDT switch circuit shown in FIG. 1.

FIG. 4 is a graph illustrating a simulation result of S-parameters in a reception mode of the SPDT switch circuit shown in FIG. 1.

FIG. 5 is a circuit diagram illustrating an SPDT switch according to another exemplary embodiment of the present disclosure.

FIG. 6 is a flowchart illustrating a method of operating an SPDT switch according to an exemplary embodiment of the present disclosure.

### DETAILED DESCRIPTION OF THE EMBODIMENTS

For a clearer understanding of the features and advantages of the present disclosure, exemplary embodiments of the present disclosure will be described in detail with reference to the accompanying drawings. However, it should be understood that the present disclosure is not limited to particular embodiments disclosed herein but includes all modifications, equivalents, and alternatives falling within the spirit and scope of the present disclosure. In the drawings, similar or corresponding components may be designated by the same or similar reference numerals.

The terminologies including ordinals such as “first” and “second” designated for explaining various components in this specification are used to discriminate a component from the other ones but are not intended to be limiting to a specific component. For example, a second component may be referred to as a first component and, similarly, a first component may also be referred to as a second component without departing from the scope of the present disclosure. As used herein, the term “and/or” may include a presence of one or more of the associated listed items and any and all combinations of the listed items.

In the description of exemplary embodiments of the present disclosure, “at least one of A and B” may mean “at least one of A or B” or “at least one of combinations of one or more of A and B”. In addition, in the description of exemplary embodiments of the present disclosure, “one or more of A and B” may mean “one or more of A or B” or “one or more of combinations of one or more of A and B”.

When a component is referred to as being “connected” or “coupled” to another component, the component may be directly connected or coupled logically or physically to the other component or indirectly through an object therebetween. Contrarily, when a component is referred to as being “directly connected” or “directly coupled” to another component, it is to be understood that there is no intervening object between the components. Other words used to describe the relationship between elements should be interpreted in a similar fashion.

The terminologies are used herein for the purpose of describing particular exemplary embodiments only and are not intended to limit the present disclosure. The singular forms include plural referents as well unless the context clearly dictates otherwise. Also, the expressions “comprises,” “includes,” “constructed,” “configured” are used to refer a presence of a combination of stated features, numbers, processing steps, operations, elements, or components, but are not intended to preclude a presence or addition of another feature, number, processing step, operation, element, or component.

Unless defined otherwise, all terms used herein, including technical or scientific terms, have the same meaning as commonly understood by those of ordinary skill in the art to which the present disclosure pertains. Terms such as those defined in a commonly used dictionary should be interpreted as having meanings consistent with their meanings in the context of related literatures and will not be interpreted as having ideal or excessively formal meanings unless explicitly defined in the present application.

Meanwhile, one or more conventional components may be included in a configuration of the present disclosure if necessary, and such components will be described herein to an extent that it does not obscure the technical idea and concept of the present disclosure. If the description of the conventional components may obscure the technical idea and concept of the present disclosure, however, detailed description of such components may be omitted for simplicity.

Exemplary embodiments of the present disclosure will now be described in detail with reference to the accompanying drawings. In the drawings, the same components may be designated by the same reference numerals to facilitate overall understanding of the disclosure, and duplicate descriptions thereof will be omitted for simplicity.

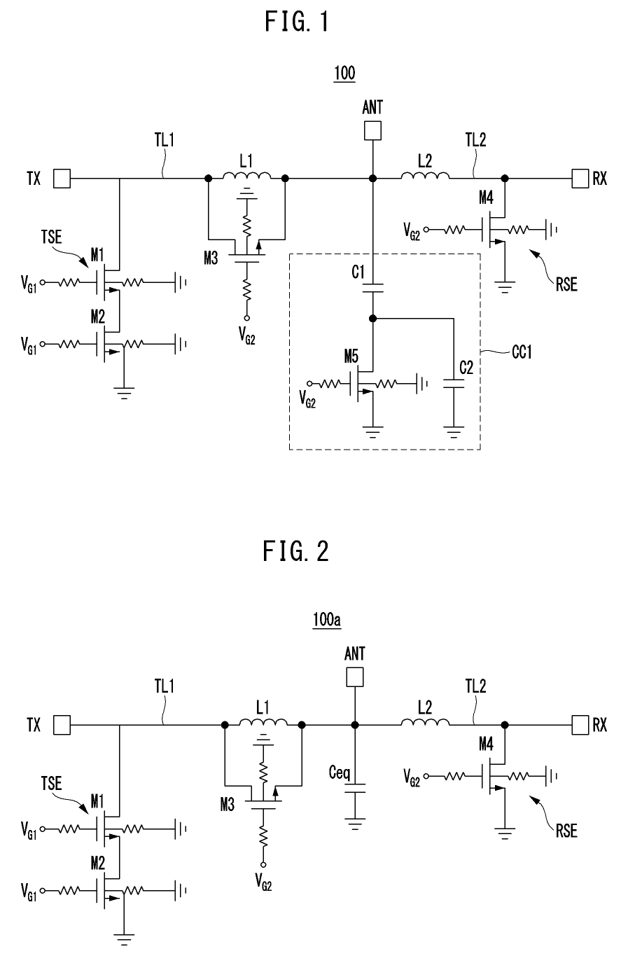

FIG. 1 is a circuit diagram illustrating an SPDT switch according to an exemplary embodiment of the present disclosure.

As shown in FIG. 1, an SPDT switch 100 according to an exemplary embodiment of the present disclosure is a single pole double throw (SPDT) switch operating in a transmission mode and a reception mode, and includes a transmission terminal TX, a reception terminal RX, an antenna terminal ANT, and an impedance control circuit CC1.

The transmission terminal TX is applied with a transmission signal, and the reception terminal RX is delivered with a reception signal. In an exemplary embodiment, the transmission signal and the reception signal may include a radio frequency (RF) signal, and the SPDT switch may be an RF SPDT switch.

An RF switch may be used as an important component in various high-frequency application fields such as communication, radar, satellite communication, and broadband signal processing equipment, and may perform functions such as transmission and reception switching, signal path selection, and multiplexing in a wireless system. An RF SPDT switch is advantageous for power distribution and selective signal transmission related to such RF signals and may play an important role in various systems.

The antenna terminal ANT is connected to the transmission terminal TX and the reception terminal RX, and based on the transmission mode, transmits the transmission signal received from the transmission terminal TX via a first transmission line TL1 to outside, and based on the reception mode, receives the reception signal from outside and delivers the reception signal to the reception terminal RX via a second transmission line TL2.

The antenna terminal ANT may be, for example, a common port for transmission and reception commonly used for transmitting and receiving RF signals, and only one port is selectively connected through switching operations so that interference between transmission and reception may be prevented.

The SPDT switch 100 may include the first transmission line TL1 and the second transmission line TL2, and may have two switching paths. Specifically, the SPDT switch 100 may operate such that one of the paths of the first transmission line TL1 connected to the transmission terminal TX and the second transmission line TL2 connected to the reception terminal RX is selected to be connected to the antenna terminal ANT according to a control signal applied from outside.

The impedance control circuit CC1 is connected between the antenna terminal ANT and ground, and includes at least two capacitors C1 and C2 and a switching element M5. The impedance control circuit CC1 adjusts a composite capacitance between the antenna terminal ANT and ground according to ON/OFF operations of the switching element M5.

The switching element M5 operates in ON/OFF states depending on the transmission mode and the reception mode. The switching element M5 may include, for example, a transistor. As shown in FIG. 1, a driving voltage V_{G2} applied from outside may be applied to a gate terminal of the switching element M5 via a resistor. Although the switching element M5 is illustrated as a single transistor in FIG. 1, the switching element M5 may alternatively stack a plurality of transistors.

In the impedance control circuit CC1, the composite capacitance configured by the capacitors C1 and C2 is changed according to an ON/OFF signal input to the switching element M5, and by the change of such a composite capacitance, the first capacitor C1 and the second capacitor C2 may operate in series or in parallel in the transmission mode and the reception mode, or one of the capacitors is deactivated, thereby providing relatively large and small composite capacitance values between the antenna terminal ANT and ground. As a result, an optimized impedance value advantageous to each mode or a signal band of each mode may be matched according to the transmission mode and the reception mode, thereby providing an optimized impedance environment. Accordingly, an effect of reducing insertion loss and improving reception sensitivity, and an effect of suppressing leakage signals and improving isolation may be obtained.

FIG. 2 is a circuit diagram illustrating an equivalent capacitance representing a composite capacitance of an impedance control circuit of the SPDT switch in FIG. 1.

As shown in FIG. 2, the impedance control circuit CC1 of an SPDT switch 100a may express, as an equivalent capacitance Ceq, a composite capacitance between the antenna terminal ANT and ground that is formed by the first capacitor C1 and the second capacitor C2 operating in series or in parallel, or with one of the capacitors deactivated, depending on the transmission mode and the reception mode.

As for the equivalent capacitance Ceq, the value thereof is advantageous for insertion loss as the value becomes larger in the transmission mode and is advantageous for insertion loss as the value becomes smaller in the reception mode. Therefore, by using such characteristics, values of a first composite capacitance of the transmission mode and a second composite capacitance of the reception mode may be appropriately adjusted so that composite capacitances (equivalent capacitances) of the transmission mode and the reception mode operate with different values.

In an exemplary embodiment, the impedance control circuit CC1 may provide the first composite capacitance in the transmission mode and may provide the second composite capacitance smaller than the first composite capacitance in the reception mode. That is, the equivalent capacitance Ceq has the first composite capacitance in the transmission mode and has the second composite capacitance in the reception mode, and the impedance control circuit CC1 may be designed such that the first composite capacitance of the transmission mode has a value greater than the second composite capacitance of the reception mode.

In general, when a plurality of capacitors are connected in parallel, a composite capacitance has a large value, and when a plurality of capacitors are connected in series, a composite capacitance has a small value. Therefore, in an exemplary embodiment, the impedance control circuit CC1 may form the first composite capacitance by connecting a plurality of capacitors in parallel in the transmission mode, or may form the second composite capacitance by connecting a plurality of capacitors in series in the reception mode.

As shown in FIG. 1, in an exemplary embodiment, the impedance control circuit CC1 may include a first capacitor C1 connected between the antenna terminal ANT and ground, and a second capacitor C2 connected between the first capacitor C1 and ground, and the switching element M5 may be connected between the first capacitor C1 and ground and may be connected in parallel with the second capacitor C2.

In an exemplary embodiment, the switching element M5 may operate in an ON state in the transmission mode such that among the first capacitor C1 and the second capacitor C2, the second capacitor C2 is deactivated and only the first capacitor C1 operates, and may operate in an OFF state in the reception mode such that the first capacitor C1 and the second capacitor C2 operate in series.

Therefore, the first composite capacitance in the transmission mode has C1, and the second composite capacitance in the reception mode has C1×C2/(C1+C2) smaller than C1. Accordingly, the equivalent capacitance Ceq has a larger value in the transmission mode than in the reception mode, which may be advantageous for insertion loss.

As described above, in FIG. 1, an exemplary embodiment has been described in which the first composite capacitance of the transmission mode has a value larger than the second composite capacitance of the reception mode. However, depending on a circuit configuration, the second composite capacitance of the reception mode may have a value larger than the first composite capacitance of the transmission mode, and in this case, V_{G1} may be input as a driving voltage applied to the switching element M5 instead of V_{G2}. In addition, if necessary, a driving voltage signal terminal may be left floating.

The switching element M5 may include a transmission-side switching element TSE.

The transmission-side switching element TSE may be connected in parallel with the first transmission line TL1 formed between the transmission terminal TX and the antenna terminal ANT.

The transmission-side switching element TSE may include a multi-stack switching element (for example, M1 and M2; see FIG. 1).

The transmission-side switching element TSE may include, for example, transistors stacked with at least two or more, and as shown in FIG. 1, a driving voltage V_{G1} applied from outside may be applied to a gate terminal of the transmission-side switching element TSE via a resistor.

The transmission-side switching element TSE may include a plurality of transistors, and in an exemplary embodiment, as shown in FIG. 1, two transistors M1 and M2 are connected in series with each other, one side of which is connected to the transmission terminal TX and another side of which may be connected to ground.

Meanwhile, when the transmission-side switching element TSE is a multi-stack transistor, the transistors M1 and M2 may both be high-voltage transistors, or only some (for example, M1) may be a high-voltage transistor.

The SPDT switch 100 may include a reception-side switching element RSE.

The reception-side switching element RSE may be connected in parallel with the second transmission line TL2 formed between the reception terminal RX and the antenna terminal ANT.

The reception-side switching element RSE may include, for example, a transistor M4, and as shown in FIG. 1, a driving voltage V_{G2} applied from outside may be applied to a gate terminal of the reception-side switching element RSE via a resistor.

In FIG. 1, the reception-side switching element RSE may be connected at one side to the reception terminal RX and at another side to ground.

According to the above configuration, based on the transmission-side switching element TSE being in an OFF state and the reception-side switching element RSE being in an ON state, the first transmission line TL1 is activated and the second transmission line TL2 is deactivated so that the transmission mode may operate, and based on the transmission-side switching element TSE being in an ON state and the reception-side switching element RSE being in an OFF state, the first transmission line TL1 is deactivated and the second transmission line TL2 is activated so that the reception mode may operate.

In an exemplary embodiment, the SPDT switch 100 may further include a first inductor L1 connected in series with the transmission terminal TX on the first transmission line TL1, and a second inductor L2 connected in series with the reception terminal RX on the second transmission line TL2.

Accordingly, the first and second inductors L1 and L2 may compensate RF characteristics in a path of high-frequency signals. For example, the first and second inductors L1 and L2 may reduce a loss of RF signals that may occur during switching, may perform functions such as impedance matching, prevention of performance degradation in high-frequency bands, and improvement of isolation between ports, and may reduce a loss of RF signals that may occur during switching.

In particular, in the transmission mode, the first capacitor C1 and the second inductor L2 may resonate at a corresponding frequency and may have a large impedance, and in the reception mode, the first and second capacitors C1 and C2 and the first inductor L1 may resonate at a corresponding frequency and may have a large impedance.

Specifically, in the transmission mode, since the switching element M5 operates in an ON state such that among the first capacitor C1 and the second capacitor C2, the second capacitor C2 is deactivated and only the first capacitor C1 operates, the first capacitor C1 and the second inductor L2 may resonate at the corresponding frequency and may have a large impedance. In addition, in the reception mode, since the switching element M5 operates in an OFF state such that the first capacitor C1 and the second capacitor C2 operate in series, the first and second capacitors C1 and C2 and the first inductor L1 may resonate at the corresponding frequency and may have a large impedance.

The SPDT switch 100 may further include a switching element M3 connected in parallel with the first inductor L1. The switching element M3 may be turned on in the transmission mode and simplified as a resistance, and insertion loss may be reduced by making the value of this resistance small.

Meanwhile, the third transmission line TL3 connected to the antenna terminal ANT may include a relatively small inductor, and other necessary elements may also be employed.

The circuit configuration shown in FIG. 1 has a relatively simple structure, while, by the impedance control circuit adjusting a composite capacitance between the antenna terminal and ground according to ON/OFF operations of the switching element, insertion loss may be reduced, and signal quality and noise figure may be improved. In addition, a high-performance SPDT switch capable of signal switching in wireless communication equipment or RF application fields may be provided even in high-frequency and ultra-high-frequency bands.

Hereinafter, simulation results of the SPDT switch 100 will be described with reference to the drawings.

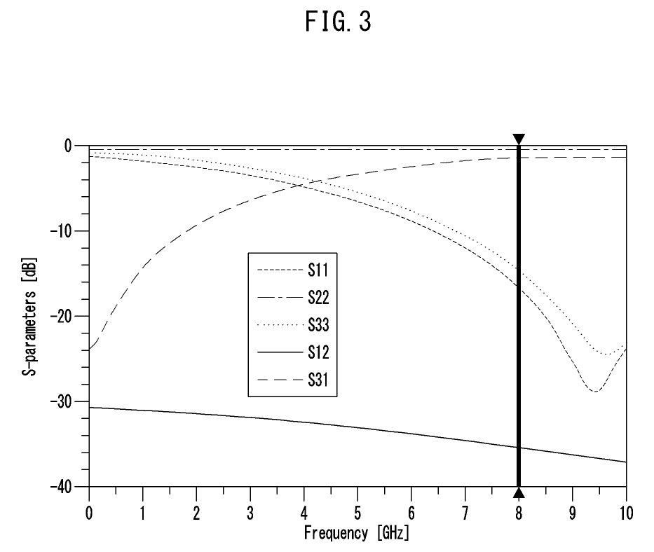

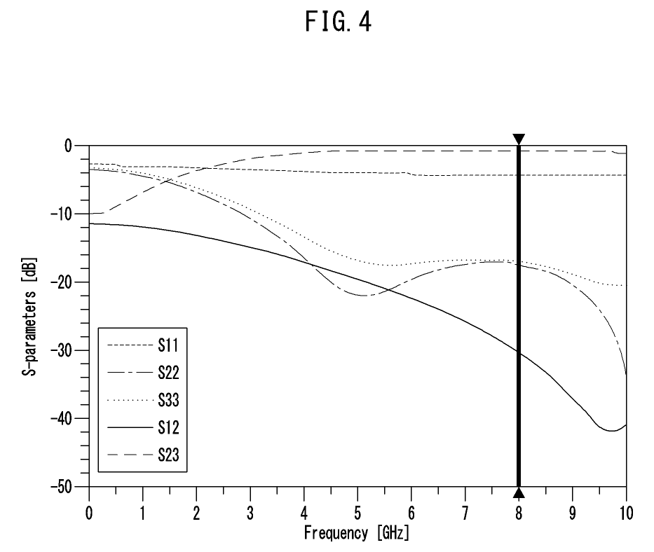

FIG. 3 is a graph illustrating a simulation result of S-parameters in a transmission mode of the SPDT switch circuit shown in FIG. 1. FIG. 4 is a graph illustrating a simulation result of S-parameters in a reception mode of the SPDT switch circuit shown in FIG. 1.

FIGS. 3 and 4 show results of simulations performed using a PC-based circuit analysis tool to include operations at a frequency of 8 GHz for the transmission mode and the reception mode of the SPDT switch circuit shown in FIG. 1.

As shown in FIGS. 3 and 4, port 1 denotes the transmission terminal TX, port 2 denotes the reception terminal RX, and port 3 denotes the antenna terminal ANT.

As shown in FIG. 3, in the transmission mode simulation, an S31 value representing a transmission characteristic from port 1 to port 3 is measured as -1.38 dB, indicating that insertion loss of the transmission path is small and a great transmission efficiency is obtained.

In addition, an S12 value representing an isolation characteristic is measured as -35.4 dB, confirming that high isolation between port 1 and port 2 is secured.

An S11 representing a reflection coefficient characteristic of port 1 is -16.6 dB, and an S33 representing a reflection coefficient characteristic of port 3 is -14.5 dB, confirming that impedance matching characteristics between the transmission port and the antenna port are also good.

As shown in FIG. 4, in the reception mode simulation, an S23 value representing an insertion loss characteristic from port 3 to port 2 is measured as -0.95 dB, confirming that the reception path also provides great transmission characteristics.

In addition, an S12 value representing an isolation characteristic is measured as -30.6 dB, confirming that high isolation between port 1 and port 2 is secured also in the reception mode.

An S22 representing a reflection coefficient characteristic of port 2 is -17.7 dB, and an S33 representing a reflection coefficient characteristic of port 3 is -17.3 dB, confirming that impedance matching characteristics between the reception port and the antenna port are also good.

From the above results, it may be seen that the circuit of FIG. 1, based on a configuration including an impedance control circuit, is capable of transmission and reception switching in a high-frequency band of about 8 GHz while securing switch characteristics in which insertion loss is low and isolation is maintained high in each mode.

In particular, by achieving an insertion loss of -1.38 dB and an isolation of -35.4 dB in the transmission mode, and also implementing a low insertion loss of -0.95 dB and an isolation characteristic of -30.6 dB in the reception mode, it may be utilized as an SPDT switch structure suitable for a high-performance RF communication system.

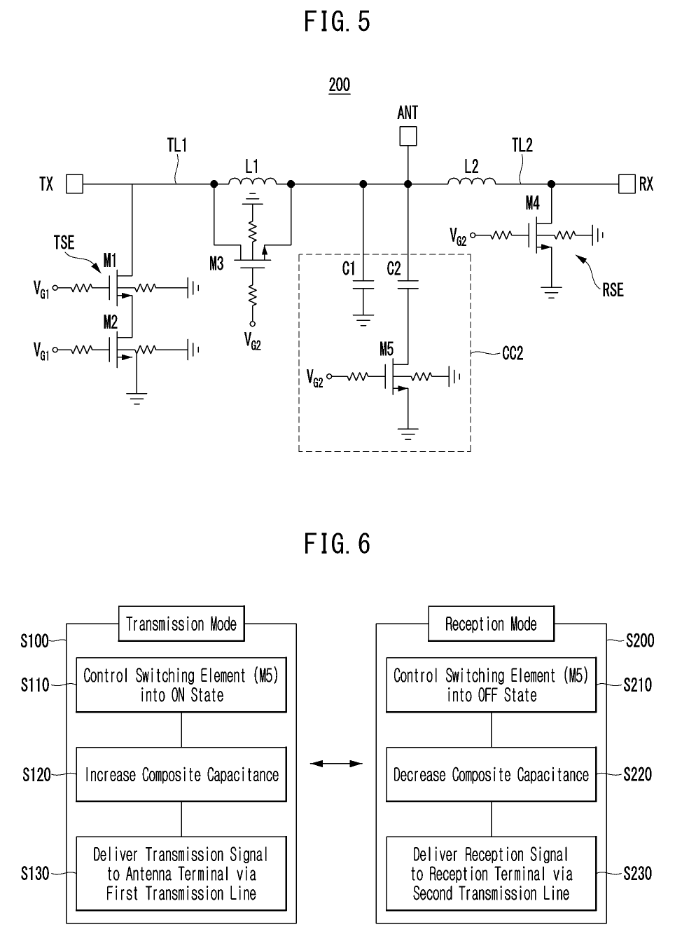

FIG. 5 is a circuit diagram illustrating an SPDT switch according to another exemplary embodiment of the present disclosure.

As shown in FIG. 5, an SPDT switch 200 according to another exemplary embodiment of the present disclosure is an SPDT switch operating in a transmission mode and a reception mode, and includes a transmission terminal TX, a reception terminal RX, an antenna terminal ANT, and an impedance control circuit CC2.

The SPDT switch 200 of FIG. 5 is substantially the same as the SPDT switch 100 of FIG. 1 (see FIG. 1), except for the impedance control circuit CC2, and thus a repetitive detailed description is omitted.

Similar to FIGS. 1 and 2, the impedance control circuit CC2 may provide a first composite capacitance in the transmission mode and may provide a second composite capacitance smaller than the first composite capacitance in the reception mode. That is, the equivalent capacitance Ceq has the first composite capacitance in the transmission mode and has the second composite capacitance in the reception mode, and the impedance control circuit CC2 may be designed such that the first composite capacitance of the transmission mode has a value greater than the second composite capacitance of the reception mode.

In general, when a plurality of capacitors are connected in parallel, a composite capacitance has a large value, and when a plurality of capacitors are connected in series, a composite capacitance has a small value. Therefore, in an exemplary embodiment, the impedance control circuit CC2 may form the first composite capacitance by connecting a plurality of capacitors in parallel in the transmission mode, or may form the second composite capacitance by connecting a plurality of capacitors in series in the reception mode.

As shown in FIG. 5, in an exemplary embodiment, the impedance control circuit CC2 may include a first capacitor C1 connected between the antenna terminal ANT and ground, and a second capacitor C2 connected between the antenna terminal ANT and ground in parallel with the first capacitor C1, and the switching element M5 may be connected in series between the second capacitor C2 and ground.

In an exemplary embodiment, the switching element M5 may operate in an ON state in the transmission mode such that the first capacitor C1 and the second capacitor C2 operate in parallel, and may operate in an OFF state in the reception mode such that among the first capacitor C1 and the second capacitor C2, the second capacitor C2 is deactivated and only the first capacitor C1 operates.

Therefore, the first composite capacitance in the transmission mode has C1+C2, and the second composite capacitance in the reception mode has C1 smaller than C1+C2. Accordingly, since the equivalent capacitance Ceq has a larger value in the transmission mode than in the reception mode, it may be advantageous for insertion loss.

In FIG. 5, a configuration is illustrated in which the second capacitor C2 and the switching element M5 are connected in order between the antenna terminal ANT and ground, but alternatively, a configuration in which the switching element M5 and the second capacitor C2 are connected in order may be adopted. That is, one terminal of the second capacitor C2 may be connected to ground and another terminal may be connected to a source of the switching element M5. In addition, in FIG. 5, in an exemplary embodiment, only one combination of the second capacitor C2 and the switching element M5 is illustrated, but the combination may be expanded in parallel to a plurality, and the switching element M5 may also stack a plurality of transistors in addition to a single transistor.

Similar to FIG. 1, the SPDT switch 200 may further include a first inductor L1 connected in series with the transmission terminal TX on the first transmission line TL1, and a second inductor L2 connected in series with the reception terminal RX on the second transmission line TL2.

Accordingly, the first and second inductors L1 and L2 may compensate RF characteristics in a path of high-frequency signals. For example, the first and second inductors L1 and L2 may reduce a loss of RF signals that may occur during switching, may perform functions such as impedance matching, prevention of performance degradation in high-frequency bands, and improvement of isolation between ports, and may reduce a loss of RF signals that may occur during switching.

In particular, in the transmission mode, the first and second capacitors C1 and C2 and the second inductor L2 may resonate at a corresponding frequency and may have a large impedance, and in the reception mode, the first capacitor C1 and the first inductor L1 may resonate at a corresponding frequency and may have a large impedance.

Specifically, in the transmission mode, since the switching element M5 operates in an ON state such that the first capacitor C1 and the second capacitor C2 operate in parallel, the first and second capacitors C1 and C2 and the second inductor L2 may resonate at the corresponding frequency and may have a large impedance. In addition, in the reception mode, since the switching element M5 operates in an OFF state such that among the first capacitor C1 and the second capacitor C2, the second capacitor C2 is deactivated and only the first capacitor C1 operates, the first capacitor C1 and the first inductor L1 may resonate at the corresponding frequency and may have a large impedance.

The SPDT switch 200 may further include a switching element M3 connected in parallel with the first inductor L1. The switching element M3 may be turned on in the transmission mode and simplified as a resistance, and insertion loss may be reduced by making the value of this resistance small.

Meanwhile, the SPDT switches described in FIGS. 1-5 may be applied to an RF signal transmission system, a wireless communication system, an RF transceiver module, or an RF power control apparatus.

In addition, the SPDT switch may also be utilized as an RF front-end module for a base station, in a configuration of a shared antenna port for transmission and reception, or in smart antenna beam control or multiple beam selection.

In an exemplary embodiment, when the SPDT switch described in FIGS. 1-5 is adopted in a wireless communication system, the wireless communication system may include a transmitter, a receiver, and the SPDT switch.

In this case, the transmitter transmits a transmission signal, the receiver receives a reception signal, and the SPDT switch is connected respectively to the transmitter and the receiver, shares a common antenna, and may operate in a transmission mode and a reception mode. This SPDT switch may be the SPDT switch described in FIGS. 1-5.

FIG. 6 is a flowchart illustrating a method of operating an SPDT switch according to an exemplary embodiment of the present disclosure.

In an exemplary embodiment, the SPDT switch may be the SPDT switches 100 and 200 described in FIGS. 1-5, may operate in a transmission mode and a reception mode, and may include a transmission terminal TX to which a transmission signal is applied, a reception terminal RX to which a reception signal is delivered, and an antenna terminal ANT connected to the transmission terminal TX and the reception terminal RX.

Referring to FIGS. 1-6, a method of operating the SPDT switch may be switched and may operate, between a transmission mode S100 and a reception mode S200.

In the transmission mode S100, the switching element M5 is controlled into an ON state in step S110, a composite capacitance between the antenna terminal ANT and ground is increased in step S120, and the transmission signal may be delivered from the transmission terminal TX to the antenna terminal ANT via the first transmission line TL1 in step S130.

In addition, in the reception mode S200, the switching element M5 is controlled into an OFF state in step S210, a composite capacitance between the antenna terminal ANT and ground is decreased in step S220, and a reception signal from outside is received via the antenna terminal ANT and may be delivered to the reception terminal RX via the second transmission line TL2 in step S230.

As described above, by increasing or decreasing a composite capacitance between the antenna terminal ANT and ground according to ON/OFF operations of the switching element M5 depending on the transmission mode and the reception mode, insertion loss may be reduced, and signal quality and noise figure may be improved.

The method of operating the SPDT switch may be applied to the SPDT switches 100 and 200 illustrated in FIGS. 1-5.

According to the above-described SPDT switch and the method of operating the SPDT switch, an impedance control circuit adjusts a composite capacitance between the antenna terminal and ground according to ON/OFF operations of the switching element, so that insertion loss can be reduced, and signal quality and noise figure can be improved.

In addition, power output in a transmission path can be increased, signal quality in a reception path can be enhanced, and low insertion loss of the SPDT switch in the reception path can improve a noise figure of a receiver.

Furthermore, a high-performance SPDT switch capable of signal switching in wireless communication equipment or RF application fields can be provided even in high-frequency and ultra-high-frequency bands.

Although the preferred exemplary embodiments of the present disclosure have been described above, those skilled in the art will understand that the present disclosure may be variously modified and changed within the scope of the spirit and region of the present disclosure set forth in the claims below.

What is claimed is:

1. A single pole double throw (SPDT) switch operating in a transmission mode and a reception mode, comprising:
a transmission terminal to which a transmission signal is applied;
a reception terminal to which a reception signal is delivered;
an antenna terminal connected to the transmission terminal and the reception terminal, configured to transmit the transmission signal received from the transmission terminal via a first transmission line to outside based on a transmission mode, and to receive the reception signal from outside and deliver the reception signal to the reception terminal via a second transmission line based on a reception mode; and
an impedance control circuit connected between the antenna terminal and ground, the impedance control circuit including at least two capacitors and a switching element operating in ON/OFF states depending on the transmission mode and the reception mode, and configured to adjust a composite capacitance between the antenna terminal and ground according to ON/OFF operations of the switching element.

2. The SPDT switch of claim 1, wherein the impedance control circuit provides a first composite capacitance in the transmission mode and provides a second composite capacitance smaller than the first composite capacitance in the reception mode.

3. The SPDT switch of claim 2, wherein the impedance control circuit forms the first composite capacitance by connecting a plurality of capacitors in parallel in the transmission mode, or forms the second composite capacitance by connecting a plurality of capacitors in series in the reception mode.

4. The SPDT switch of claim 1, wherein the impedance control circuit comprises:
a first capacitor connected between the antenna terminal and ground; and
a second capacitor connected between the first capacitor and ground, and
wherein the switching element is connected between the first capacitor and ground and is connected in parallel with the second capacitor.

5. The SPDT switch of claim 4, wherein the switching element operates in an ON state in the transmission mode such that among the first capacitor and the second capacitor, the second capacitor is deactivated and only the first capacitor operates, and operates in an OFF state in the reception mode such that the first capacitor and the second capacitor operate in series.

6. The SPDT switch of claim 1, wherein the impedance control circuit comprises:
a first capacitor connected between the antenna terminal and ground; and
a second capacitor connected between the antenna terminal and ground in parallel with the first capacitor, and
wherein the switching element is connected in series between the second capacitor and ground.

7. The SPDT switch of claim 6, wherein the switching element operates in an ON state in the transmission mode such that the first capacitor and the second capacitor operate in parallel, and operates in an OFF state in the reception mode such that among the first capacitor and the second capacitor, the second capacitor is deactivated and only the first capacitor operates.

8. The SPDT switch of claim 1, further comprising a transmission-side switching element connected in parallel with the first transmission line formed between the transmission terminal and the antenna terminal.

9. The SPDT switch of claim 8, wherein the transmission-side switching element comprises a plurality of switching elements connected in series such that one side is connected to the transmission terminal and the other side is connected to ground.

10. The SPDT switch of claim 1, further comprising a reception-side switching element connected in parallel with the second transmission line formed between the reception terminal and the antenna terminal.

11. The SPDT switch of claim 1, further comprising a transmission-side switching element connected in parallel with the first transmission line formed between the transmission terminal and the antenna terminal, and a reception-side switching element connected in parallel with the second transmission line formed between the reception terminal and the antenna terminal,
wherein based on the transmission-side switching element being in an OFF state and the reception-side switching element being in an ON state, the first transmission line is activated and the second transmission line is deactivated such that the transmission mode operates, and
based on the transmission-side switching element being in an ON state and the reception-side switching element being in an OFF state, the first transmission line is deactivated and the second transmission line is activated such that the reception mode operates.

12. The SPDT switch of claim 1, further comprising a first inductor connected in series with the transmission terminal on the first transmission line.

13. The SPDT switch of claim 1, further comprising a second inductor connected in series with the reception terminal on the second transmission line.

14. The SPDT switch of claim 1, wherein the transmission signal and the reception signal include a radio frequency (RF) signal.

15. A wireless communication system, comprising:
a transmitter configured to transmit a transmission signal;
a receiver configured to receive a reception signal; and
an SPDT switch connected respectively to the transmitter and the receiver, sharing a common antenna, and operating in a transmission mode and a reception mode,
wherein the SPDT switch comprises:
a transmission terminal to which the transmission signal is applied;
a reception terminal to which the reception signal is delivered;
an antenna terminal connected to the transmission terminal and the reception terminal, configured to transmit the transmission signal received from the transmission terminal via a first transmission line to outside based on the transmission mode, and to receive the reception signal from outside and deliver the reception signal to the reception terminal via a second transmission line based on the reception mode; and
an impedance control circuit connected between the antenna terminal and ground, the impedance control circuit including at least two capacitors and a switching element operating in ON/OFF states depending on the transmission mode and the reception mode, and configured to adjust a composite capacitance between the antenna terminal and ground according to ON/OFF operations of the switching element.

16. The wireless communication system of claim 15, wherein the impedance control circuit provides a first composite capacitance in the transmission mode and provides a second composite capacitance smaller than the first composite capacitance in the reception mode.

17. The wireless communication system of claim 15, wherein the impedance control circuit comprises a first capacitor connected between the antenna terminal and ground, and a second capacitor connected between the first capacitor and ground, and the switching element is connected between the first capacitor and ground and is connected in parallel with the second capacitor,
wherein the switching element operates in an ON state in the transmission mode such that among the first capacitor and the second capacitor, the second capacitor is deactivated and only the first capacitor operates, and operates in an OFF state in the reception mode such that the first capacitor and the second capacitor operate in series.

18. The wireless communication system of claim 15, wherein the impedance control circuit comprises a first capacitor connected between the antenna terminal and ground, and a second capacitor connected between the antenna terminal and ground in parallel with the first capacitor, and the switching element is connected in series between the second capacitor and ground,
wherein the switching element operates in an ON state in the transmission mode such that the first capacitor and the second capacitor operate in parallel, and operates in an OFF state in the reception mode such that among the first capacitor and the second capacitor, the second capacitor is deactivated and only the first capacitor operates.

19. The wireless communication system of claim 15, further comprising:
a first inductor connected in series with the transmission terminal on the first transmission line; and
a second inductor connected in series with the reception terminal on the second transmission line.

20. A method of operating an SPDT switch that operates in a transmission mode and a reception mode, and includes a transmission terminal to which a transmission signal is applied, a reception terminal to which a reception signal is delivered, and an antenna terminal connected to the transmission terminal and the reception terminal, the method comprising:
in the transmission mode, controlling a switching element into an ON state to increase a composite capacitance between the antenna terminal and ground, and delivering the transmission signal from the transmission terminal to the antenna terminal via a first transmission line; and
in the reception mode, controlling the switching element into an OFF state to decrease the composite capacitance between the antenna terminal and ground, and receiving the reception signal from outside via the antenna terminal and delivering the reception signal to the reception terminal via a second transmission line.
